(19) United States
(12) Patent Application Publication
(10) Pub. No.: US 2025/0215318 A1
(43) Pub. Date: Jul. 3, 2025

(54) ETCHING COMPOSITION, ETCHING METHOD USING SAME, AND METHOD FOR MANUFACTURING ELECTRONIC COMPONENT

(71) Applicant: TOKYO OHKA KOGYO CO., LTD., Kawasaki-shi (JP)

(72) Inventors: Po Ting CHOU, Kawasaki-shi (JP); Ming-Yen CHUNG, Kawasaki-shi (JP)

(21) Appl. No.: 18/851,962

(22) PCT Filed: Apr. 13, 2023
(86) PCT No.: PCT/JP2023/015039

§ 371 Date: Sep. 27, 2024

(30) Foreign Application Priority Data
Apr. 20, 2022 (TW) 111115066

(51) Int. Cl. C09K 13/00; H01L 21/311; H01L 21/3213

(52) U.S. Cl. CPC C09K 13/00; H01L 21/31111; H01L 21/32134

(57) ABSTRACT

An etching composition which selectively removes an etching target, the etching composition including an amine compound containing a tertiary amine, and an oxidizing agent. The etching composition may also contain at least one of an alkali compound, an organic solvent, water, a chelating agent, and a surfactant.

### DESCRIPTION

### Technical Field

The present invention relates to an etching composition for etching titanium nitride and/or tungsten carbide (also referred to as tungsten-doped carbon) at a high etching rate and a high etching selectivity (also referred to as an etching rate ratio) in the presence of a metal underlayer containing aluminum, cobalt, copper, nickel, manganese, or ruthenium, a substrate, or a low dielectric constant (Low-k) material such as silica or polyimide, an etching method using the same, and a method for manufacturing an electronic component.

Priority is claimed on Taiwan Patent Application No. 111115066 filed in Taiwan on Apr. 20, 2022, the content of which is incorporated herein by reference.

### Background Art

In recent years, the development and manufacture of microelectromechanical systems (MEMS) devices and semiconductor devices using various materials have been actively performed. However, with the miniaturization and high integration of MEMS and the miniaturization of semiconductor processes, there is a demand for a technology of selectively removing metal underlayers containing aluminum, cobalt, copper, nickel, manganese, and the like, substrates, masks, or materials containing titanium nitride (TIN) and/or tungsten carbide (WC) in the manufacture of MEMS and semiconductor devices.

As a technology of selectively removing titanium nitride or silicon by chemical etching, for example, an etching method using an SC-1 solution (NH₄OH:H₂O₂:deionized water=1:1:5) is well known. Further, Patent Document 1 suggests a composition for selectively removing titanium nitride from a surface of a microelectronic device, the composition containing an oxidizing agent, an etching agent, a metal corrosion inhibitor, a chelating agent, and a solvent. Patent Document 2 suggests an aqueous cleaning composition for removing post-plasma etching residues such as titanium nitride, the aqueous cleaning composition containing an oxidizing agent, an oxidizing agent stabilizer, and water. Patent Document 3 suggests an etching solution composition for etching a titanium layer or a titanium-containing layer on an oxide semiconductor, the etching solution composition containing a compound having ammonium ions, hydrogen peroxide, and a basic compound, and having a pH of 7 to 11.

However, none of the above-described documents have examined the removal of a metal underlayer containing aluminum, cobalt, copper, nickel, manganese, ruthenium, or the like, or a layer containing tungsten and/or titanium, which is formed on a low dielectric constant material such as silica or polyimide, with a high selectivity. Therefore, at present, there is a demand for an etching composition that removes a layer containing titanium or tungsten at a high etching rate and with high etching selectivity.

### CITATION LIST

### Patent Documents

Patent Document 1: Published Japanese Translation No. 2016-527707 of the PCT International Publication

Patent Document 2: Published Japanese Translation No. 2009-512194 of the PCT International Publication

Patent Document 3: PCT International Publication No. WO2018/181896

### SUMMARY OF INVENTION

### Technical Problem

Therefore, the present invention has been made in consideration of the above-described circumstances, and an object thereof is to provide an etching composition capable of removing a layer containing tungsten and/or titanium at a high etching rate and a high etching selectivity, an etching method using the same, and a method for manufacturing an electronic component.

### Solution to Problem

In order to achieve the above-described object, the present invention employs the following configurations.

According to a first aspect of the present invention, there is provided an etching composition which selectively removes an etching target, the etching composition including: an amine compound containing a tertiary amine; and an oxidizing agent.

The etching composition may further contain an alkali compound.

The etching composition according to claim 2, in which the alkali compound is at least one or more selected from the group consisting of ammonia, an alkali metal hydroxide, an alkali metal carbonate, an alkali metal bicarbonate, an alkali metal hydride, and an ammonium compound represented by Formula (1).

NR¹R²R³R⁴OH (1)

(In the formula, R¹ to R⁴ each independently represent a hydrogen atom, a hydroxyl group, a chain-like or branched alkyl group having 1 to 12 carbon atoms, or a chain-like or branched alkoxyl group having 1 to 12 carbon atoms, where the alkyl group and the alkoxyl group may be further substituted with an oxygen atom, a nitrogen atom, or a hydroxy group.)

It is preferable that the oxidizing agent contains one or more selected from a peroxide, an inorganic acid, and an organic acid.

The etching composition may further contain an organic solvent.

It is preferable that the etching composition is an aqueous etching solution containing water.

The etching composition may further contain at least one selected from a chelating agent and a surfactant. The tertiary amine may or may not contain a cyclic tertiary amine compound.

According to a second aspect of the present invention, there is provided an etching method including: an etching treatment step of etching an etching target that contains tungsten or titanium using the etching composition.

According to a third aspect of the present invention, there is provided a method for manufacturing an electronic component, the method including: performing etching on silicon nitride or tungsten carbide using the etching composition.

The above-described embodiments of the present invention can be used alone or in combination thereof.

### Advantageous Effects of Invention

According to the present invention, it is possible to provide an etching composition that can achieve a high etching rate and a high etching selectivity for an etching target, particularly a metal layer containing tungsten or titanium, an etching method using the same, and a method for manufacturing an electronic component.

### DESCRIPTION OF EMBODIMENTS

Hereinafter, each embodiment of the present invention will be described in detail.

### [Etching Composition]

A composition according to a first aspect of the present invention is an etching composition that selectively removes an etching target and contains an amine compound containing a tertiary amine and an oxidizing agent.

### <Amine Compound Containing Tertiary Amine>

The amine compound containing a tertiary amine used in the present invention is a component that primarily acts as an etchant for removing a material containing titanium, a material containing tungsten, and particularly titanium nitride (TIN) or tungsten carbide (WC).

The tertiary amine compound that can be used in the present invention is a compound represented by Formula: NR⁵R⁶R⁷. R⁵, R⁶, and R⁷ in the formula each independently represent a hydrogen atom, a halogen atom, a hydroxyl group, a chain-like or branched alkyl group which may be substituted, or a chain-like or branched alkoxy group which may be substituted. Further, any two of R⁵, R⁶, and R⁷ may be bonded to each other to form a hydrocarbon ring or a heterocyclic ring having a heteroatom. Examples of the heteroatom include an oxygen atom, a nitrogen atom, a sulfur atom, a phosphorus atom, and a halogen atom.

Examples of halogen atoms include fluorine atoms, chlorine atoms, bromine atoms, and iodine atoms.

Examples of the alkyl group include a linear or branched alkyl group having 1 to 12 carbon atoms such as a methyl group, an ethyl group, a propyl group, a butyl group, an isobutyl group, a 2-ethylbutyl group, a pentyl group, a hexyl group, an octyl group, a 1,2-dimethyloctyl group, a decyl group, an isodecyl group, or a dodecyl group, and examples of the alkoxy group include a linear or branched alkoxy group having 1 to 12 carbon atoms such as a methoxy group, an ethoxy group, a propoxy group, a butoxy group, a t-butoxy group, a pentoxy group, a hexanoxy group, an isohexanoxy group, an octoxy group, an isooctoxy group, a decyloxy group, or a dodecyloxy group.

Specific examples of chain-like or branched tertiary amines include trimethylamine, triethylamine, tripropylamine, tributylamine, N,N-dimethylisobutylamine, N,N-diethylisobutylamine, N-methyldiethanolamine, N-ethyldiethanolamine, N,N-dimethylethanolamine, N,N-diethylethanolamine, triethanolamine, N,N-diisopropylethylamine, N,N,N′,N′-tetramethylethylenediamine, N,N,N′,N′-tetramethylpropylenediamine, N,N,N′,N″,N″-pentamethyldiethylenetriamine, N,N,N′,N″,N″-pentamethyl-(3-aminopropyl)ethylenediamine, N,N,N′,N″,N″-pentamethyldipropylenetriamine, and N,N,N′,N′-tetramethylguanidine.

Specific examples of cyclic tertiary amines include saturated cyclic tertiary amines such as N-methylpyrrolidine, N-ethylpyrrolidine, N-methylpiperidine, N-ethylpiperidine, N,N′-dimethylpiperazine, N,N′-dimethyl-1,4-diazacycloheptane, N-methylmorpholine, 1,4-diazabicyclo[2.2.2]octane, and N-aminopropylmorpholine, and unsaturated cyclic tertiary amines such as pyridine, pyrazine, quinoline, isoquinoline, acridine, quinoxaline, cinnoline, pteridine, N-methylimidazole, N-methylimidazoline, N-methylpyrazole, diazabicycloundecene, and diazabicyclononene. The number of carbon atoms in the cyclic tertiary amine is preferably, for example, in a range of 4 to 30.

The above-described tertiary amines may be used alone or in combination of two or more kinds thereof, or commercially available products may also be used. However, the present invention is not limited thereto.

Among the above-described tertiary amines, the chain-like or branched tertiary amines are preferable. In addition, from the viewpoint of cost performance, chain-like or branched trialkylamine, hydroxydialkylamine, dihydroxyalkylamine, dialkylalkoxyamine, monoalkyldialkoxyamine, and the like are more preferable. Among these, a tertiary amine containing 1 or more and 3 or less hydroxy groups is more preferable, and a tertiary amine containing 1 or 2 hydroxy groups is still more preferable. The content proportion of these suitable hydroxy group-containing tertiary amines in the amine compound containing tertiary amines is preferably 75% by weight or greater, more preferably 90% by weight or greater, and still more preferably 100% by weight.

The blending amount of the amine compound containing a tertiary amine is preferably 0.01% by weight or greater 20.0% by weight or less with respect to the total amount of the etching composition. Here, the total amount of the etching composition denotes the total amount of all components such as the amine compound containing tertiary amines, the oxidizing agent described below, the alkali compound described below as necessary, other additives described below as necessary, and the remaining water (including the water contained in the components) (the same applies hereinafter). In addition, the blending amounts may also fall within the following ranges.

The lower limit of the blending amount of the amine compound containing a tertiary amine may be, for example, 0.05% by weight or greater, 0.10% by weight or greater, 0.15% by weight or greater, 0.20% by weight or greater, 0.25% by weight or greater, 0.30% by weight or greater, 0.40% by weight or greater, 0.50% by weight or greater, 0.75% by weight or greater, 1.0% by weight or greater, 1.5% by weight or greater, 2.0% by weight or greater, 2.5% by weight or greater, 3.0% by weight or greater, 4.0% by weight or greater, or 5.0% by weight or greater, and the upper limit thereof may be, for example, 19.0% by weight or less, 18.0% by weight or less, 17.0% by weight or less, 15.0% by weight or less, 12.0% by weight or less, 10.0% by weight or less, or 8.0% by weight or less. In addition, the upper limit and the lower limit may be used in any combination. For example, the combination thereof may be 0.05% by weight or greater and 10.0% by weight or less, and is not limited to specific combinations.

In addition, in a case where two or more kinds of tertiary amines are used in combination, the blending ratio is not particularly limited and may be adjusted according to the etching conditions or the desired etching rate.

Further, a primary amine or a secondary amine may be blended as the amine compound in addition to the tertiary amine within a range where the effects of the present invention are not impaired. The primary amine or the secondary amine is not particularly limited, but is preferably an amine containing a hydroxyl group or an alkoxyl group, or monoalkylamine or dialkylamine containing an alkyl group having 1 to 10 carbon atoms. In the case of blending the primary amine or the secondary amine, the blending amount thereof is preferably 25% by weight or less, more preferably 15% by weight or less, and still more preferably 5% by weight or less with respect to the total amount of the amine compound. In other words, the amine compound may substantially consist only of tertiary amines.

The use or the addition amount of the primary amine or the secondary amine may be adjusted according to the etching target, the desired etching rate, and the etching selectivity.

### <Oxidizing Agent>

The oxidizing agent is a component used in the etching composition according to the present invention for oxidizing TiN to TiNOx and/or for oxidizing W to WOx. The oxidizing agent used in the present invention is not limited as long as the oxidizing agent can oxidize the etching target, particularly TiN and/or WC. For example, at least one selected from an organic peroxide, an inorganic peroxide, an organic acid (salt), an inorganic acid (salt), and a metal acid salt may be used. The etching target or non-etching target may be appropriately selected as necessary. Further, the non-etching target denotes, for example, an underlying layer containing metals such as aluminum, cobalt, copper, nickel, and manganese, a substrate, a mask, and the like.

More specific examples of the oxidizing agent include peroxides such as hydrogen peroxide (H₂O₂), t-butyl peroxide, cumene hydroperoxide, p-menthane hydroperoxide, di-t-butyl peroxide, t-butyl cumyl peroxide, acetyl peroxide, isobutyryl peroxide, and octanoyl peroxide; inorganic acids such as nitric acid (HNO₃), phosphoric acid (H₃PO₄), iodic acid (HIO₃), metaperiodic acid (HIO₄), and orthoperiodie acid (H₅IO₆); organic acids such as peracetic acid (CH₃(CO)OOH); metal acid salts such as potassium hypochlorite (KClO), silver nitrate (AgNO₃), iron nitrate (Fe(NO₃)₃),nickel nitrate (Ni(NO₃)₂), magnesium sulfate (Mg(NO₃)₂), sodium persulfate (Na₂S₂O₈), potassium peroxodisulfate (K₂S₂ O₈), potassium permanganate (KMnO₄), and potassium dichromate (K₂Cr₂O₇); and inorganic acid salts such as ammonium chlorite (NH₄ClO₂), ammonium chlorate (NH₄ClO₃), ammonium iodate (NH₄IO₃), ammonium nitrate (NH₄NO₃), ammonium perborate (NH₄BO₃), ammonium perchlorate (NH₄ClO₄), ammonium periodate (NH₄IO₄), ammonium persulfate ((NH₄)₂S₂O₈), and ammonium hypochlorite (NH₄ClO). However, the present invention is not limited thereto.

From the viewpoint of the cost and environmental friendliness, the oxidizing agent is preferably a peroxide, an inorganic acid, or an organic acid and more preferably a peroxide, particularly hydrogen peroxide (H₂O₂).

The oxidizing agent may be used alone or in combination of two or more kinds thereof, and a commercially available product may also be used. In addition, in a case where two or kinds of the above-described oxidizing agents are used in combination, the blending ratio is not particularly limited and may be adjusted according to the etching conditions, the desired etching rate, and the etching selectivity. Further, the above-described organic acids (salts) and inorganic acids (salts) can also act as pH adjusters or buffering agents.

As for the blending amount of the oxidizing agent, it cannot be uniformly determined depending on the kinds of etching targets or oxidizing agents, but as a general guideline, the blending amount is preferably 0.5% by weight or greater and 60.0% by weight or less with respect to the total amount of the etching composition. In addition, the blending amounts may also fall within the following ranges.

The lower limit of the blending amount of the oxidizing agent may be, for example, 0.6% by weight or greater, 0.8% by weight or greater, 1.0% by weight or greater, 2.0% by weight or greater, 5.0% by weight or greater, 7.0% by weight or greater, 10.0% by weight or greater, 12.0% by weight or greater, 15.0% by weight or greater, 18.0% by weight or greater, or 20.0% by weight or greater, and the upper limit thereof may be, for example, 57.5% by weight or less, 55.0% by weight or less, 52.5% by weight or less, 50.0% by weight or less, 47.5% by weight or less, 45.0% by weight or less, 42.5% by weight or less, 40.0% by weight or less, 35.0% by weight or less, or 30% by weight or less. In addition, the upper limit and the lower limit may be used in any combination. For example, the blending amount thereof may be 10.0% by weight or greater and 40.0% by weight or less, and is not limited to a specific combination.

### <Alkali Compound>

The etching composition according to the present invention may or may not further contain an alkali compound. The alkali compound is an auxiliary component used to increase or stabilize the etching rate or etching selectivity. In addition, from another viewpoint, the alkali compound is also a component that acts as an inhibitor to suppress etching of non-etching targets. Therefore, the etching rate and the etching selectivity can be well-balanced by adding a predetermined amount of the alkali compound to the tertiary amine.

The alkali compound is at least one or more selected from the group consisting of ammonia, an alkali metal hydroxide, an alkali metal carbonate, an alkali metal bicarbonate, an alkali metal hydride, and an ammonium compound represented by Formula (1).

NR¹R²R³R⁴OH (1)

(In the formula, R¹ to R⁴ each independently represent a hydrogen atom, a hydroxyl group, a chain-like or branched alkyl group having 1 to 12 carbon atoms, or a chain-like or branched alkoxyl group having 1 to 12 carbon atoms, where the alkyl group and the alkoxyl group may be further substituted with an oxygen atom, a nitrogen atom, or a hydroxy group.)

Specific examples of the alkali metal hydroxide include lithium hydroxide, sodium hydroxide, and potassium hydroxide, specific examples of the alkali metal carbonate include lithium carbonate, sodium carbonate, and potassium carbonate, specific examples of the alkali metal bicarbonate include lithium hydrogen carbonate, sodium hydrogen carbonate, and potassium hydrogen carbonate, and specific examples of the alkali metal hydride include lithium hydride, sodium hydride, and potassium hydride.

Specific examples of the ammonium compound represented by Formula (1) include tetramethylammonium hydroxide (TMAH), tetraethylammonium hydroxide, tetrapropylammonium hydroxide, tetrabutylammonium hydroxide (TBAH), ethyltrimethylammonium hydroxide, hydroxyethyltrimethylammonium hydroxide, methyltri(hydroxyethyl)ammonium hydroxide, tetra(hydroxyethyl)ammonium hydroxide, tetrahexylammonium hydroxide, tetraheptylammonium hydroxide, tetraoctylammonium hydroxide, butyltrimethylammonium hydroxide, methyltripentylammonium hydroxide, dibutyldipentylammonium hydroxide, dihydroxyethyldimethylammonium hydroxide, monohydroxyethyltriethylammonium hydroxide, dihydroxyethyldiethylammonium hydroxide, trihydroxyethylmonoethylammonium hydroxide, monohydroxypropyltrimethylammonium hydroxide, dihydroxypropyldimethylammonium hydroxide, trihydroxypropylmonomethylammonium hydroxide, monohydroxypropyltriethylammonium hydroxide, dihydroxypropyldiethylammonium hydroxide, and trihydroxypropylmonoethylammonium hydroxide.

From the viewpoint of achieving both a high etching rate and a high etching selectivity, it is preferable that ammonia or an ammonium compound represented by Formula (1) is used as the alkali compound. In addition, from the viewpoints of the cost, the handleability, and the availability, it is most preferable to use ammonia.

The blending amount of the alkali compound cannot be uniformly determined depending on the kinds of the etching target, the non-etching target, and the tertiary amine, but in general, it is preferable that the blending amount thereof is small. For example, the blending amount of the alkali compound can be set to greater than 0 ppm and 12000 ppm or less with respect to the total amount of the etching composition. In addition, the blending amount can also be set to be in the following ranges.

For example, the lower limit of the blending amount of the alkali compound can be set to 5 ppm or greater, 10 ppm or greater, 20 ppm or greater, 25 ppm or greater, 50 ppm or greater, 75 ppm or greater, 100 ppm or greater, 200 ppm or greater, 300 ppm or greater, 500 ppm or greater, 750 ppm or greater, or 1000 ppm or greater. The upper limit of the blending amount of the alkali compound can be set to 11000 ppm or less, 10000 ppm or less, 9000 ppm or less, 8000 ppm or less, 7000 ppm or less, 6000 ppm or less, 5000 ppm or less, 4000 ppm or less, or 3000 ppm or less.

The upper limit and the lower limit may be used in any combination. For example, the blending amount thereof may be 25 ppm or greater and 8000 ppm or less, and is not limited to a specific combination. As described above, since the blending amount of the alkali compound cannot be uniformly determined depending on the kinds of the etching target, the non-etching target, and the tertiary amine, the upper limit (or the lower limit) of the blending amount of the alkali compound can be used as the lower limit (or the upper limit) of the blending amount. For example, in a case of an alkali metal bicarbonate, the blending amount thereof can be set to 10 ppm or greater and 1000 ppm or less.

The alkali compounds may be used alone or in combination of two or more kinds thereof, and a commercially available product may also be used. In addition, in a case where two or more kinds of the above-described alkali compounds are used in combination, the blending ratio is not particularly limited and can be adjusted according to the etching conditions, the desired etching rate, or the etching selectivity.

### <Organic Solvent>

The etching composition of the present invention may further contain an organic solvent. The etching composition of the present invention may or may not further contain an organic solvent. The organic solvent is an auxiliary component for adjusting the etching rate or etching selectivity. In addition, from another viewpoint, the organic solvent is also a component for controlling or suppressing etching of the non-etching targets.

In a case of using an organic solvent, the organic solvent may be any of water-soluble or water-insoluble, and it is preferable to use a water-soluble organic solvent. Specific examples of the organic solvent include the followings.

Examples of the organic solvent include linear or branched alcohol solvents having 1 to 22 carbon atoms, such as methanol, ethanol, propanol, isopropyl alcohol, pentanol, neopentyl alcohol, t-amyl alcohol, hexyl alcohol, 3,3-dimethyl-1-butanol, 2-methyl-2-pentanol, 3-methyl-3-pentanol, octanol, 2,2,4-trimethyl-1-pentanol, 2-ethylhexanol, nonanol, 3,7-dimethyl-3-octanol, 3,3,5-trimethyl-1-hexanol, 3-ethyl-2,2-dimethyl-3-pentanol, decanol, 3,7-dimethyl-1-octanol, trihexylmethanol, dodecanol, tetradecanol, cetanol, stearyl alcohol, icosanol, and docosanol;

alkanediol-based solvents such as methanediol, cthanediol, propanediol, butanediol, pentanediol, hexanediol, heptanediol, octanediol, nonanediol, and decanediol;

saturated alicyclic alcohol-based solvents such as cyclopropanemethanol, 1-methylcyclopropanemethanol, 2-methylcyclopropanemethanol, cyclobutanol, cyclobutanemethanol, cyclopentanol, cyclopentanemethanol, 3-cyclopentyl-1-propanol, 1-methylcyclopentanol, 2-methylcyclopentanol, 3-methylcyclopentanol, cyclohexylmethanol, dicyclohexylmethanol, menthol, cyclohexanol, 2-cyclohexylethanol, 1-cyclohexylethanol, 3-cyclohexylpropanol, 4-cyclohexyl-1-butanol, 1-methylcyclohexanol, 2-methylcyclohexanol, 2-ethylcyclohexanol, 2-t-butylcyclohexanol, 3-methylcyclohexanol, 4-methylcyclohexanol, 4-ethylcyclohexanol, 4-t-butylcyclohexanol, 4-t-amylcyclohexanol, 2,3-dimethylcyclohexanol, 2-adamantanol, 1-adamantanemethanol, 1-adamantaneethanol, 2-methyl-2-adamantanol, 3,5-dimethylcyclohexanol, and 3,3,5,5-tetramethylcyclohexanol; and

alkoxy group-containing alcohol-based solvents such as 2-methoxyethanol, 2-ethoxyethanol, 2-propoxyethanol, 2-isopropoxyethanol, 2-butoxyethanol, 2-cyclohexyloxyethanol, 3-methoxy-1-butanol, and 3-methoxy-3-methyl-1-butanol.

Further, non-alcohol-based solvents can also be used.

Examples of the non-alcohol-based solvents include alkylene glycol alkyl ether-based solvents such as ethylene glycol monoethyl ether, ethylene glycol monopropyl ether (EGPE), ethylene glycol monobutyl ether, diethylene glycol monomethyl ether, diethylene glycol monoethyl ether, diethylene glycol monopropyl ether, diethylene glycol monobutyl ether, diethylene glycol monohexyl ether (DEGHE), triethylene glycol monomethyl ether, triethylene glycol monoethyl ether, tricthylene glycol monopropyl ether, propylene glycol monomethyl ether, propylene glycol monoethyl ether, propylene glycol monopropyl ether, dipropylene glycol monomethyl ether (DPM), tripropylene glycol monomethyl ether, tripropylene glycol monoethyl ether, and tripropylene glycol monopropyl ether;

alkylene glycol ether acetate-based solvents such as ethylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monoethyl ether acetate,diethylene glycol monopropyl ether acetate, diethylene glycol monobutyl ether acetate, diethylene glycol monophenyl ether acetate, triethylene glycol monomethyl ether acetate, triethylene glycol monoethyl ether acetate, triethylene glycol monopropyl ether acetate, triethylene glycol monobutyl ether acetate, triethylene glycol monophenyl ether acetate, propylene glycol monomethyl ether acetate (PGMEA), propylene glycol monoethyl ether acetate, propylene glycol monopropyl ether acetate, propylene glycol monobutyl ether acetate, propylene glycol monophenyl ether acetate, dipropylene glycol monomethyl ether acetate, dipropylene glycol monoethyl ether acetate, dipropylene glycol monopropyl ether acetate, dipropylene glycol monobutyl ether acetate,dipropylene glycol monophenyl ether acetate, tripropylene glycol monomethyl ether acetate, tripropylene glycol monoethyl ether acetate, tripropylene glycol monopropyl ether acetate, tripropylene glycol monobutyl ether acetate, tripropylene glycol monophenyl ether acetate, 1,3-butylene glycol monomethyl ether acetate (3-methoxybutyl acetate), 1,3-butylene glycol monoethyl ether acetate, 1,3-butylene glycol monopropyl ether acetate, 1,3-butylene glycol monobutyl ether acetate, and 1,3-butylene glycol monophenyl ether acetate;

ester-based solvents such as 3-methoxybutanol acetate, tetrahydrofurfuryl acetate, cyclohexanol acetate, methyl lactate, ethyl lactate, ethyl pyruvate, butyl acetate, methyl 3-methoxypropionate, ethyl 3-ethoxypropionate, methyl 2-hydroxypropionate, ethyl 2-hydroxypropionate, ethyl 2-hydroxy-2-methylpropionate, methyl 2-hydroxy-3-methylbutanoate, tert-butyl acetate, tert-butyl propionate, and propylene glycol monotert-butyl ether acetate;

ketone-based solvents such as acetone, methyl ethyl ketone, methyl amyl ketone, methyl isobutyl ketone, y-butyrolactone, and cyclohexanone; and

polar solvents include tetrahydrofuran (THF), N-methyl-2-pyrrolidone (NMP), N,N-dimethylformamide (DMF), dimethylacetamide, dimethyl sulfoxide (DMSO), and sulfolane.

Among the above-described organic solvents, alkanediol-based solvents, alkylene glycol alkyl ether-based solvents, alkylene glycol alkyl ether acetate-based solvents, and polar solvents are preferable from the viewpoint that the tertiary amine and the alkali compound are easily balanced.

The blending amount of the organic solvent cannot be uniformly determined depending on the kinds of the etching target, the non-etching target, and the tertiary amine, but is typically greater than 0% by weight and 45% by weight or less with respect to the total amount of the etching composition. In addition, the blending amount can also be set to be in the following ranges.

The lower limit of the blending amount of the organic solvent may be, for example, 0.5% by weight or greater, 1.0% by weight or greater, 2.0% by weight or greater, 2.5% by weight or greater, 5% by weight or greater, 7.5% by weight or greater, 10.0% by weight or greater, 12.0% by weight or greater, 15.0% by weight or greater, 18.0% by weight or greater, or 20.0% by weight or greater, and the upper limit thereof may be, for example, 42.5% by weight or less, 40.0% by weight or less, 37.5% by weight or less, 35.0% by weight or less, 32.5% by weight or less, 30.0% by weight or less, 25% by weight or less, 22.5% by weight or less, 20.0% by weight or less, or 15% by weight or less. In addition, the upper limit and the lower limit may be used in any combination. For example, the blending amount thereof may be 10.0% by weight or greater and 30.0% by weight or less, but is not limited to a specific combination.

The organic solvent may be used alone or in combination of two or more kinds thereof. In addition, a general commercially available product may be used. In cases where two or more of the above-described organic solvents are used in combination, the blending ratio is not particularly limited and may be adjusted according to the etching conditions and the non-etching target.

### <Chelating Agent>

The etching composition of the present invention may further contain a chelating agent. The etching composition of the present invention may or may not further contain a chelating agent. Similarly to the organic solvent, the chelating agent is an auxiliary component for adjusting the etching rate or the etching selectivity. In addition, from another viewpoint, the chelating agent also serves as a corrosion inhibitor to control the etching of non-etching targets or to suppress the oxidation of metals that are etching targets. Further, a temporal change in the etching composition can be suppressed and stabilized by adding the chelating agent to the etching composition, and thus the shelf life thereof can be extended.

Typical examples of such a chelating agent include phosphoric acid, nitric acid, oxalic acid, citric acid, malonic acid, succinic acid, nitrilotriacetic acid (NTA), tannic acid, tartaric acid, gluconicacid, saccharinic acid, glyceric acid, phthalic acid, maleic acid, mandelic acid, malonic acid, ascorbic acid, salicylic acid, sulfosalicylic acid, phosphonic acid, dodecylphosphonic acid, phenylphosphonic acid, benzylphosphonic acid, hexylphosphonic acid, ethylenediaminetetraacetic acid (EDTA), butylenediaminetetraacetic acid, (1,2-cyclohexylenedinitrilo-)tetraacetic acid (CyDTA), diethylenetriaminepentaacetic acid (DETPA), ethylenediaminetetrapropionic acid, (hydroxyethyl)ethylenediaminetriacetic acid (HEDTA), (N,N,N′,N′-ethylenediaminetetra(methylenephosphonic) acid (EDTMP), triethylenetetramine hexaacetic acid (TTHA), 1,3-diamino-2-hydroxypropane-N,N,N′,N′-tetraacetic acid (DHPTA), 1-hydroxyethane-1,1-diphosphonic acid (HEDP), trans-1,2-cyclohexanediaminetetraacetic acid monohydrate (CDTA), methyliminodiacetic acid, propylenediaminetetraacetic acid, and salts thereof; benzotriazole (BTA), 5-methyl-1H-benzotriazole (5-mBTA), methyltetrazole, benzothiazole, 5-aminotetrazole, 1-hydroxybenzotriazole, 5-phenylthiol-benzotriazole, 4-ethylbenzotriazole, 5-ethylbenzotriazole, 4-propylbenzotriazole, 5-propylbenzotriazole, 4-isopropylbenzotriazole, 5-isopropylbenzotriazole, 4-n-butylbenzotriazole, 5-n-butylbenzotriazole, 4-isobutylbenzotriazole,5-isobutylbenzotriazole, 4-pentylbenzotriazole, 5-pentylbenzotriazole, 4-hexylbenzotriazole, 5-hexylbenzotriazole, 5-methoxybenzotriazole, 5-hydroxybenzotriazole, dihydroxypropylbenzotriazole, 6-methylbenzotriazole, imidazole, benzimidazole, 2-mercapto-1,3-propanediol, and 3-mercapto-1,2-propanediol.

Among the above-described examples, preferred chelating agents include EDTA, CDTA, CyDTA, BTA, HDTA, HEDP, and 5-mBTA. Basically, the above-described chelating agent may be appropriately selected based on the material of the non-etching target and the desired etching selectivity. However, the present invention is not limited to the above-described examples. In the present invention, the above-described chelating agents may also be referred to as corrosion inhibitors or pH adjusters.

The blending amount of the chelating agent cannot be uniformly determined depending on the kinds of the etching target, the non-etching target, and the organic solvent, but is typically greater than 0% by weight and 10% by weight or less with respect to the total amount of the etching composition. In addition, the blending amount can also be set to be in the following ranges.

The lower limit of the blending amount of the chelating agent may be, for example, 0.005% by weight or greater, 0.010% by weight or greater, 0.025% by weight or greater, 0.050% by weight or greater, 0.075% by weight or greater, 0.10% by weight or greater, 0.20% by weight or greater, 0.25% by weight or greater, 0.30% by weight or greater, 0.40% by weight or greater, or 0.50% by weight or greater, and the upper limit thereof may be, for example, 9.5% by weight or less, 9.0% by weight or less, 8.5% by weight or less, 8.0% by weight or less, 7.0% by weight or less, 6.0% by weight or less, 5.0% by weight or less, 4.0% by weight or less, 3.0% by weight or less, or 2.0% by weight or less. In addition, the upper limit and the lower limit may be used in any combination. For example, the blending amount thereof may be 0.010% by weight or greater and 5.0% by weight or less, but is not limited to a specific combination.

The chelating agent may be used alone or in combination of two or more kinds thereof. In addition, a general commercially available product may be used. In cases where two or more kinds of the above-described chelating agents are used in combination, the blending ratio is not particularly limited and may be appropriately adjusted as necessary.

### <Other Additives>

Additional additives other than the above-described components may be further added to the etching composition of the present invention as necessary. Examples of the other additives include pH adjusters, buffering agents, coupling agents, leveling agents, colorants, and surfactants, but the present invention is not limited thereto, and any additives commonly added to etching compositions can be used. In addition, the other additives may be used alone or in combination of two or more kinds thereof.

The pH adjuster and the buffer agent to be added to the etching composition of the present invention may be appropriately selected from the examples of the organic acids (salts) and the inorganic acids (salts) described above in the sections of the oxidizing agent and the chelating agent.

The surfactant to be added to the etching composition of the present invention may be an anionic, cationic, nonionic, or amphoteric surfactant.

Specifically, examples of the anionic surfactant include lauryl sulfate, polyoxyethylene lauryl ether sulfate, polyoxyethylene alkyl ether sulfate, polyoxyalkylene alkenyl ether sulfate, alkylbenzene sulfonic acid, alkylbenzene sulfonate, alkylnaphthalenesulfonate, dialkylsulfosuccinate, alkyl diphenyl ether disulfonate, alkanesulfonate, and alkenylsuccinate, examples of the cationic surfactant include an alkylamine salt type surfactant such as n-hexylamine, n-octylamine, n-decylamine, or n-dodecylamine, and a quaternary ammonium salt such as lauryltrimethylammonium chloride or stearyltrimethylammonium chloride, examples of the nonionic surfactant include polyethylene glycol alkyl ether, polyethylene glycol alkyl phenyl ether, propylene glycol alkyl ether, glycerol alkyl ester, polyoxyethylene glycol sorbitan alkyl ester, sorbitan alkyl ester, a block copolymer of polyethylene glycol and polypropylene glycol, and a fluorine surfactant, and examples of the amphoteric surfactant include sodium cocaminopropionate, sodium stearylaminopropionate, sodium laurylaminoacetate, sodium laurylaminopropionate, sodium N-lauroyl-N′-carboxymethyl-N′-hydroxyethyl ethylenediamine, stearyldimethylaminoacetic acid betaine, lauryldimethylaminoacetic acid betaine, lauric acid amidopropyl betaine, lauryldihydroxyethyl betaine, palm oil fatty acid amidopropyldimethylaminoacetic acid betaine, and 2-alkyl-N-carboxymethyl-N-hydroxyethyl imidazolinium betaine.

The surfactant may be used alone or in combination of two or more kinds thereof, and a general commercially available product may be used. In cases where two or more kinds of the above-described surfactants are used in combination, the blending ratio is not particularly limited and may be adjusted as necessary by those skilled in the art.

In addition, the blending amount of the other additives (total amount of the other additives) is not particularly limited, but is preferably 5% by weight or less and more preferably 3% by weight or less with respect to the total amount of the etching composition.

In some aspects, the etching composition of the present invention does not contain or does not substantially contain any or all of the above-described pH adjusters, buffering agents, coupling agents, leveling agents, colorants, or surfactants that can be added to the composition.

### <Water>

The etching composition of the present invention contains an amine compound containing the above-described tertiary amine, an oxidizing agent, and, as necessary, an alkali compound, a chelating agent, or other additives, and the remaining amount is adjusted with water. That is, the etching composition of the present invention is an aqueous etching solution containing water in addition to the above-described components.

As the water, distilled water, ultrafiltered water, deionized water, ion exchange water, RO water, pure water, or ultrapure water is preferably used.

<pH>

The etching composition according to the present invention is preferably a weakly acidic to alkaline aqueous solution and more preferably an aqueous solution having a pH of 4 or greater and 10 or less. Further, from the viewpoint of workability and safety, it is more preferable that the etching composition is an aqueous solution having a pH of 5 or greater and 9 or less. In addition, the pH may be adjusted by a general pH adjuster, the above-described chelating agent, or the like.

### <Abrasive>

The etching composition of the present invention can be used to some extent as a CMP polishing slurry, for example, as a polishing liquid used in the final stage of a polishing step, but the etching composition does not contain any abrasive grains such as silica or alumina and solid abrasives as long as the composition is used as an etching composition.

### [Method of Preparing Etching Composition]

A method of preparing the etching composition according to the present invention includes a step of uniformly stirring and mixing, in a container, the amine compound containing the above-described tertiary amine, the oxidizing agent, water, and, as necessary, the alkali compound, the chelating agent, and other additives, In one aspect, it is preferable that the alkali compound, the chelating agent, water, and other additives are mixed with the amine compound containing the tertiary amine, and then the oxidizing agent is added thereto. It is more preferable that the alkali compound, the chelating agent, and other additives are mixed with the amine compound containing the tertiary amine in advance to prepare a preliminary liquid, water is added to the preliminary liquid immediately before the etching treatment is performed, and the oxidizing agent is finally added thereto. By adding water and the oxidizing agent before the etching treatment is performed, the shelf life of the etching composition according to the present invention can be extended.

The amine compound containing the tertiary amine, the oxidizing agent, water, and as necessary, the alkali compound, the chelating agent, or other additives can be mixed at once, but the shelf life of the etching composition may be shortened due to the action of the oxidizing agent depending on the kinds of the tertiary amine, the alkali compound, and the chelating agent.

Meanwhile, there is a possibility that fine particles (aggregates) may be generated in a case of mixing these components depending on the kinds of the tertiary amine, the alkali compound, and the chelating agent. In such a case, the mixed solution may be filtered through a filter. As for the filter, a filter commonly used in the manufacture of chemical liquids used in the semiconductor processes can be used without particular limitation. Specific examples of the filter include sintered filters, depth filters, and membrane filters. Examples of the filter material include fluororesins such as polytetrafluoroethylene (PTFE), polyamide resins such as nylon, and polyolefin resins such as polyethylene and polypropylene (PP) (including resins with a high density and an ultrahigh molecular weight). The pore size of the filter is not limited, as long as the generated fine particles (aggregates) are removed. Further, the number of times the filtration is performed may be only once or a plurality of times.

In addition, the method of stirring in a container is not particularly limited, and the stirring can be performed using a stirrer such as a magnetic stirrer, or a commercially available stirrer such as a mechanical stirrer. Any general stirring method can be applied.

### [Etching Method]

The etching method of the present invention includes a step of performing an etching treatment on the etching target using the above-described etching composition. As the etching target, a metal layer containing tungsten or titanium is preferable.

A method of performing the etching treatment is not particularly limited, and a known etching method can be used. Examples of such a method include a dipping method, a liquid filling method (paddle method), and a spraying method, but the present invention is not limited to these methods.

In the dipping method, the etching target is dipped in the etching composition of the present invention, and the etching composition is brought into contact with the etching target.

In the spraying method, for example, the etching target is transported or rotates in a predetermined direction, and the etching composition of the present invention is sprayed onto the position, and the etching composition is brought into contact with the etching target. As necessary, the etching composition may be sprayed while the etching target rotates using a spin coater.

In the liquid filling method, the etching target is covered with the etching composition so that the etching target and the etching composition are brought into contact with each other.

These methods of the etching treatment can be appropriately selected according to the structure, the material, and the like of the etching target. In a case of the spraying method or the liquid filling method, the supply amount of the etching composition to the etching target is not particularly limited and may be an amount in which a surface of the etching target to be treated is sufficiently wet with the etching composition.

Further, the purpose of the etching treatment is not particularly limited, and may be fine processing of a surface of the etching target to be treated, containing TiN or WC (for example, a tungsten-containing layer on a substrate or a titanium-containing layer on a wafer), the removal of tungsten-containing deposits adhering to the object to be treated (for example, a substrate including a tungsten layer), or the cleaning of the surface of the object to be treated, which contains TiN.

The temperature at which the etching treatment is performed is not particularly limited, and may be a temperature at which the etching composition dissolves a tungsten-containing layer or a titanium-containing layer. The temperature for the etching treatment, that is, the temperature of the etching composition in a case of performing the etching treatment may be in a range from 15° C. to lower than the boiling point of the composition and is preferably in a range of 20° C. to 80° C. In any of the spraying method, the dipping method, or the liquid filling method, the etching rate increases as the temperature of the etching agent increases, and thus it is desirable to appropriately select the treatment temperature in consideration of the safety, the cost, and the handleability.

Further, the etching method of the present invention may include optional steps in addition to the etching treatment step. Examples of the optional steps include a step of performing a rinsing treatment. The rinsing treatment and a rinsing liquid for the rinsing treatment may be appropriately selected from known methods and known rinsing liquids for semiconductor treatments and then used.

### [Method for Manufacturing Electronic Component]

A method for manufacturing an electronic component according to the present invention includes a step of performing an etching treatment on the etching target containing tungsten or titanium, using the etching composition of the present invention.

The step of performing an etching treatment on the object to be treated, which contains tungsten or titanium, can be performed by the same method as described in [Etching Method] above. The object to be treated, which contains tungsten or titanium, is preferably a substrate, a mask, a pellicle, or a wafer having a tungsten-containing layer or a titanium-containing layer. As the substrate, a substrate typically used for manufacturing electronic components can be used.

### EXAMPLES

Hereinafter, the present invention will be described in more detail based on examples, but the present invention is not limited to these examples.

### [Preparation of Etching Composition]

The amine compound, the alkali compound, the organic solvent, and the chelating agent listed in Tables 1 and 2 were sequentially added to a container (for example, a beaker) in the blending amounts (% by weight) indicated in the parentheses of the tables to prepare a preliminary solution. The preliminary solution was sufficiently stirred with a magnetic stirrer to obtain a uniform solution. It was visually confirmed that the preliminary solution did not contain any suspended materials or precipitates. Next, deionized water was added to the preliminary solution such that the amount of each component in the preliminary solution reached the blending amount indicated in the parentheses of the tables, thereby setting the total amount of the preliminary solution to 100% by weight. Further, an oxidizing agent was added to the solution at the volume ratio listed in the tables to prepare the etching compositions of Examples 1 to 32 and Comparative Examples 1 to 9. In Tables 1 and 2, the blending amount described in the parentheses “( )” are in units of % by weight except for the oxidizing agent and the alkali compound.

Each abbreviation listed in Tables 1 and 2 represents the following meanings.

### <Amine Compound>

NH3: ammonia

MEA: 2-aminoethanol

1,3-DMPN: 1,3-diaminopropane

DETA: diethylenetriamine

THEA: Tetrahydrofurfurylamine

ChOH: choline hydroxide

4-NMO: 4-methylmorpholine N-oxide

TBA: tributylamine

TEA: triethanolamine

MDEA: N-methyldiethanolamine

DMEA: N,N-dimethylethanolamine

### <Alkali Compound>

NH₃

### <Organic Solvent>

DMSO: dimethylsulfoxide

PG: 1,2-propanediol

PGMEA: propylene glycol monomethyl ether acetate

DPM: dipropylene glycol methyl ether

EGPE: ethylene glycol monopropyl ether

DEGHE: diethylene glycol monohexyl ether

NMP: N-methyl-2-pyrrolidone

TPM: tripropylene glycol monomethyl ether

### <Chelating Agent>

BTA: 1,2,3-benzotriazole

5-mBTA: 5-methyl-1H-benzotriazole

1-TG: 3-mercapto-1,2-propanediol

Bn-H2PO4: benzylphosphonic acid

Hexyl-H2PO4: hexylphosphonic acid

CDTA: trans-1,2-cyclohexanediaminetetraacetic acid monohydrate

EDTA: Ethylenediaminetetraacetic acid

HEDP: 1-hydroxyethane-1,1-diphosphonic acid

### <Oxidizing Agent>

H₂O₂

### [Etching Treatment]

A blanket wafer on which WC, TiN, alumina, Co, and Cu were each formed by a sputtering method was cut into 2 cm squares to prepare a test piece (etching target). Next, the test piece was heated to 60° C. in hot water, and a beaker containing the etching composition for each example was heated to 60° C. in a hot water bath. Each test piece was subjected to an etching treatment by being dipped in the etching composition of each example.

### [Calculation of Etching Rate and Etching Selectivity]

The film thickness of the metal film formed on each wafer before and after the etching treatment was measured using a fluorescent X-ray analyzer. The etching rate (Å/min) was calculated from a difference in thickness of the test piece before and after the etching treatment. Next, the etching selectivity was calculated based on each etching rate. The results are collectively listed in Table 1 and Table 2.

### [Evaluation of Copper Oxidation]

The presence or absence of oxidation on the surface of the etched copper blanket wafer was visually confirmed. The results are collectively listed in Table 1 and Table 2.

TABLE 1

| | Etching composition | | | | | | | | | | | | | | | |
|---|---|---|---|---|---|---|---|---|---|---|---|---|---|---|---|---|
| | | | | | | Oxidizing | | | | | | Copper | | | | |
| | Amine | Alkali | | Che- | | agent | | | | | | oxi- | Etching selectivity | | | |
| | com- | com- | Organic | lating | | (volume | Etching rate (Å/min) | | | | | dation | WC/ | WC/ | TiN/ | TiN/ |
| Examples | pound | pound | solvent | agent | Water | ratio) | WC | TiN | AlOx | Co | Cu | CuOx | AlOx | Co | AlOx | Co |

| | | | | | | | | | | | | | |
|---|---|---|---|---|---|---|---|---|---|---|---|---|---|
| Comparative | NH3 | Remaining | 100% | 101.5 | — | 28.7 | 0.8 | 0.1 | Y | 4 | 127 | | |
| Example 1 | (0.9%) | amount | | | | | | | | | | | |
| Comparative | NH3 | Remaining | 200% | 71.5 | — | 68.2 | 84.2 | 194.0 | N | 1 | 1 | | |
| Example 2 | (5%) | amount | | | | | | | | | | | |
| Comparative | NH3 | Remaining | 200% | 20.7 | — | 161.0 | 7.5 | 20.8 | N | 0 | 3 | | |
| Example 3 | (10%) | amount | | | | | | | | | | | |
| Comparative | MEA | Remaining | 200% | 21.6 | — | 20.6 | 9.9 | 16.7 | N | 1 | 2 | | |
| Example 4 | (5%) | amount | | | | | | | | | | | |
| Comparative | 1,3- | Remaining | 200% | 32.2 | — | 7.1 | 7.8 | 6.3 | N | 5 | 4 | | |
| Example 5 | DMPN | amount | | | | | | | | | | | |
| | (5%) | | | | | | | | | | | | |
| Comparative | DETA | Remaining | 200% | 43.0 | — | 10.6 | 97.9 | 191.8 | N | 4 | 0 | | |
| Example 6 | (5%) | amount | | | | | | | | | | | |
| Comparative | THFA | Remaining | 200% | 33.8 | — | 12.5 | 0.1 | 3.0 | N | 3 | 423 | | |
| Example 7 | (5%) | amount | | | | | | | | | | | |
| Comparative | ChOH | Remaining | 200% | 38.9 | — | 46.5 | 0.4 | 1.4 | Y | 1 | 104 | | |
| Example 8 | (5%) | amount | | | | | | | | | | | |
| Comparative | 4-NMO | Remaining | 200% | 46 | — | 0.4 | 0.1 | 51.1 | N | 119 | 438 | | |
| Example 9 | (5%) | amount | | | | | | | | | | | |
| Example 1 | TBA | Remaining | 200% | 41.5 | — | 2.6 | 0.1 | 0.1 | Y | 16 | 415 | | |
| | (5%) | amount | | | | | | | | | | | |
| Example 2 | TEA | Remaining | 100% | 54.5 | — | 0.1 | 2.3 | 0.1 | Y | 363 | 24 | | |
| | (0.9%) | amount | | | | | | | | | | | |
| Example 3 | TEA | Remaining | 200% | 59 | — | 0.4 | 0.6 | 0.0 | Y | 152 | 93 | | |
| | (5%) | amount | | | | | | | | | | | |
| Example 4 | TEA | Remaining | 200% | 55.8 | — | 1.3 | 0.5 | 0.0 | Y | 44 | 120 | | |
| | (10%) | amount | | | | | | | | | | | |
| Example 5 | MDEA | Remaining | 200% | 37.5 | — | 0.1 | 0.1 | 0.5 | Y | 355 | 375 | | |
| | (5%) | amount | | | | | | | | | | | |
| Example 6 | MDEA | Remaining | 200% | 57.6 | — | 0.1 | 0.2 | 0.1 | Y | 576 | 346 | | |
| | (10%) | amount | | | | | | | | | | | |
| Example 7 | DMEA | Remaining | 200% | 66.5 | — | 0.7 | 0.2 | 0.0 | Y | 93 | 285 | | |
| | (5%) | amount | | | | | | | | | | | |
| Example 8 | DMEA | Remaining | 200% | 63.5 | — | 0.2 | 0.1 | 0.1 | Y | 412 | 953 | | |
| | (10%) | amount | | | | | | | | | | | |
| Example 9 | DMEA | Remaining | 100% | 61.6 | — | 0.4 | 0.5 | 0.1 | Y | 171 | 132 | | |
| | (0.9%) | amount | | | | | | | | | | | |
| Example 10 | MDEA | Remaining | 100% | 53.8 | 87.0 | 0.2 | 1.2 | 0.0 | Y | 299 | 45 | 483 | 73 |
| | (0.9%) | amount | | | | | | | | | | | |

TABLE 2
oxidation

| | Etching composition | | | | | | | | |
|---|---|---|---|---|---|---|---|---|---|
| | Amine | Alkali | Organic | Chelating | | Oxidizing agent | Etching rate (Å/min) | | |
| Examples | compound | compound | solvent | agent | Water | (volume ratio) | WC | TiN | AlOx |
| Example 11 | MDEA | NH3 (90 | | | Remaining | 100% | 82.9 | 128.4 | 0.1 |
| | (0.9%) | ppm) | | | amount | | | | |
| Example 12 | MDEA | NH3 (900 | | | Remaining | 100% | 91.6 | 257.1 | 1.5 |
| | (0.9%) | ppm) | | | amount | | | | |
| Example 13 | MDEA | NH3 (9000 | | | Remaining | 100% | 115.1 | 255.2 | 2.8 |
| | (0.9%) | ppm) | | | amount | | | | |
| Example 14 | MDEA | NH3 (900 | DMSO | | Remaining | 100% | 90.9 | 257.8 | 1.8 |
| | (0.9%) | ppm) | (30%) | | amount | | | | |
| Example 15 | MDEA | NH3 (900 | PG | | Remaining | 100% | 94.8 | 259.0 | 0.4 |
| | (0.9%) | ppm) | (30%) | | amount | | | | |
| Example 16 | MDEA | NH3 (900 | PGMEA | | Remaining | 100% | 75.7 | 47.9 | 0.0 |
| | (0.9%) | ppm) | (30%) | | amount | | | | |
| Example 17 | MDEA | NH3 (900 | DPM | | Remaining | 100% | 95.5 | 257.9 | 2.1 |
| | (0.9%) | ppm) | (30%) | | amount | | | | |
| Example 18 | MDEA | NH3 (900 | EGPE | | Remaining | 100% | 90.8 | 254.0 | 1.7 |
| | (0.9%) | (ppm) | (30%) | | amount | | | | |
| Example 19 | MDEA | NH3 (900 | DEGHE | | Remaining | 100% | 96.9 | 255.0 | 2.9 |
| | (0.9%) | ppm) | (30%) | | amount | | | | |
| Example 20 | MDEA | NH3 (900 | NMP | | Remaining | 100% | 90 | 253.3 | 0.7 |
| | (0.9%) | ppm) | (30%) | | amount | | | | |
| Example 21 | MDEA | NH3 (900 | TPM | | Remaining | 100% | 94.5 | 257.7 | 1.6 |
| | (0.9%) | ppm) | (30%) | | amount | | | | |
| Example 22 | MDEA | NH3 (900 | TPM | BTA | Remaining | 100% | 90.1 | 120.8 | 0.8 |
| | (0.9%) | (ppm) | (30%) | (2%) | amount | | | | |
| Example 23 | MDEA | NH3 (900 | TPM | imidazole | Remaining | 100% | 89.8 | 240.4 | 3.2 |
| | (0.9%) | ppm) | (30%) | (2%) | amount | | | | |
| Example 24 | MDEA | NH3 (900 | TPM | 5-m BTA | Remaining | 100% | 91.1 | 208.0 | 1.0 |
| | (0.9%) | ppm) | (30%) | (2%) | amount | | | | |
| Example 25 | MDEA | NH3 (900 | TPM | 1-TG | Remaining | 100% | 86.4 | 15.6 | 0.7 |
| | (0.9%) | ppm) | (30%) | (2%) | amount | | | | |
| Example 26 | MDEA | NH3 (900 | TPM | Bn-H2PO4 | Remaining | 100% | 95.6 | 256.8 | 0.8 |
| | (0.9%) | ppm) | (30%) | (0.1%) | amount | | | | |
| Example 27 | MDEA | NH3 (900 | TPM | Hexyl-H2PO4 | Remaining | 100% | 92.8 | 248.3 | 0.2 |
| | (0.9%) | ppm) | (30%) | 0.1% | amount | | | | |
| Example 28 | MDEA | NH3 (900 | TPM | Hexyl-H2PO4 | Remaining | 100% | 71 | 72.6 | 0.0 |
| | (0.9%) | ppm) | (30%) | (1%) | amount | | | | |
| Example 29 | MDEA | NH3 (900 | TPM | CDTA | Remaining | 100% | 92 | 251.4 | 2.3 |
| | (0.9%) | ppm) | (30%) | (0.3%) | amount | | | | |
| Example 30 | MDEA | NH3 (900 | TPM | EDTA | Remaining | 100% | 88.6 | 249.7 | 0.1 |
| | (0.9%) | ppm) | (30%) | (0.3%) | amount | | | | |
| Example 31 | MDEA | NH3 (900 | TPM | HEDP | Remaining | 100% | 111.9 | 248.5 | 0.1 |
| | (0.9%) | ppm) | (30%) | (0.3%) | amount | | | | |
| Example 32 | MDEA | NH3 (900 | TPM | CDTA | Remaining | 100% | 95.3 | 198.0 | 0.3 |
| | (0.9%) | ppm) | (30%) | (0.3%) - BTA | amount | | | | |
| | | | | (2%) | | | | | |

| | | | Copper | | | | |
|---|---|---|---|---|---|---|---|
| | Etching rate (Å/min) | | oxidation | Etching selectivity | | | |
| Examples | Co | Cu | CuOx | WC/AlOx | WC/Co | TiN/AlOx | TiN/Co |
| Example 11 | 0.1 | 0.0 | Y | 829 | 995 | 1284 | 1541 |
| Example 12 | 0.0 | 0.0 | Y | 61 | 2290 | 173 | 6426 |
| Example 13 | 2.4 | 0.0 | Y | 41 | 48 | 91 | 107 |
| Example 14 | 0.1 | 0.0 | Y | 50 | 909 | 141 | 2578 |
| Example 15 | 0.1 | 0.0 | Y | 231 | 813 | 632 | 2220 |
| Example 16 | 32.8 | 0.0 | Y | 1893 | 2 | 1198 | 1 |
| Example 17 | 0.0 | 0.0 | Y | 47 | 2865 | 126 | 7737 |
| Example 18 | 0.0 | 0.0 | Y | 53 | 2724 | 149 | 7620 |
| Example 19 | 0.1 | 0.0 | Y | 34 | 969 | 89 | 2550 |
| Example 20 | 0.1 | 0.0 | Y | 122 | 1080 | 342 | 3040 |
| Example 21 | 0.0 | 0.0 | Y | 58 | 2363 | 157 | 6443 |
| Example 22 | 1.0 | 4.3 | N | 108 | 90 | 145 | 121 |
| Example 23 | 85.1 | 18.6 | N | 28 | 1 | 75 | 3 |
| Example 24 | 0.1 | 2.8 | N | 90 | 1367 | 206 | 3120 |
| Example 25 | 204.2 | 12.5 | N | 122 | 0 | 22 | 0 |
| Example 26 | 0.1 | 0.0 | Y | 113 | 1434 | 304 | 3852 |
| Example 27 | 0.0 | 0.0 | Y | 580 | 9280 | 1552 | 24830 |
| Example 28 | 0.3 | 0.1 | Y | 7100 | 237 | 7260 | 242 |
| Example 29 | 4.4 | 2.1 | N | 40 | 21 | 108 | 57 |
| Example 30 | 99.1 | 5.0 | N | 886 | 1 | 2497 | 3 |
| Example 31 | 208.6 | 17.9 | N | 932 | 1 | 2071 | 1 |
| Example 32 | 0.01 | 1.9 | N | 318 | 9530 | 660 | 19800 |

As listed in Table 1, in Comparative Examples 1 to 9 in which an amine compound not containing a tertiary amine was used, the etching rate for tungsten carbide was high, but neither the high etching selectivity of WC/AlOx nor the high etching selectivity of WC/Co was obtained. On the contrary, in Examples 1 to 10 in which an amine compound containing a tertiary amine was used, the etching rate for tungsten carbide was high, and both the high etching selectivity of WC/AlOx and the high etching selectivity of WC/Co were obtained.

In addition, as listed in Table 2, in Examples 11 to 13 in which an alkali compound was added to the composition containing an amine compound containing a tertiary amine, the etching rate for WC and TiN could be improved, and the etching selectivity could be further improved. In Examples 14 to 21 in which the etching composition contained a tertiary amine, an alkali compound, and further an organic solvent, the etching selectivity of specific metals could be improved. Further, as shown in Examples 22 to 32, copper oxidation could be suppressed and the etching selectivity of specific metals could be improved by further adding a chelating agent to the composition containing a tertiary amine, an alkali compound, and an organic solvent.

As shown in the above-described results, according to the present invention, it is possible to provide an etching composition capable of achieving a high etching rate and a high selectivity with respect to TiN and/or WC.

Although several embodiments of the present invention have been described above, various omissions, substitutions, or modifications can be made within a range not departing from the gist of the invention. It is understood that these embodiments and the modifications thereof are included within the scope of the claims.

What is claimed is:

1. An etching composition which selectively removes an etching target, the etching composition comprising:
an amine compound containing a tertiary amine; and
an oxidizing agent.

2. The etching composition according to claim 1, further comprising an alkali compound.

3. The etching composition according to claim 2,
wherein the alkali compound is one or more selected from the group consisting of ammonia, an alkali metal hydroxide, an alkali metal carbonate, an alkali metal bicarbonate, an alkali metal hydride, and an ammonium compound represented by Formula (1),
NR¹R²R³R⁴OH (1)
wherein R¹ to R⁴ each independently represents a hydrogen atom, a hydroxyl group, a chain or branched alkyl group having 1 to 12 carbon atoms, or a chain-like or branched alkoxyl group having 1 to 12 carbon atoms, wherein the alkyl group and the alkoxyl group may be further substituted with an oxygen atom, a nitrogen atom, or a hydroxy group.

4. The etching composition according to claim 1, wherein the oxidizing agent contains one or more selected from the group consisting of a peroxide, an inorganic acid, and an organic acid.

5. The etching composition according to claim 1, further comprising an organic solvent.

6. The etching composition according to claim 1, wherein the etching composition is an aqueous etching solution containing water.

7. The etching composition according to claim 1, further comprising at least one selected from the group consisting of a chelating agent and a surfactant.

8. The etching composition according to claim 1, wherein the tertiary amine does not include a cyclic tertiary amine.

9. An etching method comprising etching an etching target that contains tungsten or titanium using the etching composition according to claim 1.

10. A method for manufacturing an electronic component, the method comprising performing etching on silicon nitride or tungsten carbide using the etching composition according to claim 1.
